(19) United States
(12) Patent Application Publication
(10) Pub. No.: US 2022/0157638 A1
(43) Pub. Date: May 19, 2022

(54) CHUCK TABLE AND LASER PROCESSING APPARATUS

(71) Applicant: DISCO CORPORATION, Tokyo (JP)

(72) Inventors: Yukiyasu MASUDA, Tokyo (JP); Hiroshi MORIKAZU, Tokyo (JP)

(21) Appl. No.: 17/453,028

(22) Filed: Nov. 1, 2021

(30) Foreign Application Priority Data
Nov. 17, 2020 (JP) 2020-190617

(51) Int. Cl. H01L 21/683; H01L 21/67

(52) U.S. Cl. CPC H01L 21/6838; B23K 26/08; H01L 21/67092

(57) ABSTRACT

There is provided a chuck table for holding a workpiece under suction. The chuck table includes a base table having a suction path to be connected to a suction source, a support member that is mounted on the base table and supports the workpiece, and a protective plate disposed so as to cover an upper surface of the support member and to protect the support member. The protective plate has a plurality of through-holes that transmits a suction force from the suction source to the workpiece.

### BACKGROUND OF THE INVENTION

### Field of the Invention

The present invention relates to a chuck table that holds a workpiece under suction, and also to a laser processing apparatus including the chuck table.

### Description of the Related Art

In a manufacturing process of device chips, a wafer with devices formed in respective regions defined by a plurality of scribe lines (hereinafter referred to as “streets”) arranged in a grid pattern is used. By dividing this wafer along the streets, the device chips are obtained with the devices included therein respectively. Such device chips are incorporated in various kinds of electronic equipment such as mobile phones and personal computers.

For the division of the wafer, a cutting apparatus is used. The cutting apparatus includes a chuck table having a holding surface to hold a workpiece, and a cutting unit with an annular cutting blade fitted thereon to cut the workpiece. With the wafer held on the holding surface of the chuck table, the cutting blade is rotated and is allowed to cut into the wafer, whereby the wafer is cut and divided.

In recent years, there is also a growing interest in technology that divides wafers by laser processing. Those proposed include, for example, a method that forms grooves in a wafer along streets by application of a laser beam (see JP H10-305420A). When an external force is applied to the wafer in which the grooves have been formed along the streets, the grooves function as division starting points, so that the wafer is divided along the streets. For the laser processing of the wafer, a laser processing apparatus is used. The laser processing apparatus includes a chuck table having a holding surface that holds a workpiece, and a laser beam application unit that applies the laser beam to the workpiece. With the wafer held on the holding surface of the chuck table, the laser beam is applied from the laser beam application unit toward the wafer, whereby predetermined laser processing is applied to the wafer.

The chuck table mounted on the above-described cutting apparatus or laser processing apparatus is constructed using a porous member of porous ceramics or the like. Further, the holding surface of the chuck table is formed by a surface of the porous member and is connected to a suction source via internal pores of the porous member. With the wafer placed on the holding surface of the chuck table, a negative pressure of the suction source is caused to act on the holding surface, whereby the wafer is held under suction on the chuck table.

However, random projections and recesses are formed on the surface of the porous member. In addition, at some areas of the surface of the porous member, adjacent recesses may be connected with each other so that large size grooves may be formed. Accordingly, the use of the porous member in the chuck table makes it difficult to form a uniform and flat holding surface. If a wafer is held by a chuck table having random projections and recesses on its holding surface, the wafer is held in a state in which the wafer is irregularly deformed along the projections and recesses of the holding surface. If the wafer is processed in this state, various processing failures may occur due to the deformations of the wafer and the projections and recesses of the holding surface. If the wafer is not held flat, for example, upon its processing by a laser processing apparatus, difficulty arises in scanning a laser beam while maintaining its condensing point at an intended depth inside the wafer. As a result, variations tend to occur in the depth position of a region inside the wafer where the laser processing is applied. Further, if a cutting blade is allowed to cut into a wafer with the wafer held on a chuck table, in which large size grooves are formed in its holding surface as described above, when processing the wafer by a cutting apparatus, the wafer comes into contact with the cutting blade in a state that the wafer is floating from the holding surface in regions where the wafer overlaps the large size grooves. As a consequence, a processing failure such as chipping becomes prone to occur on the wafer.

In a chuck table, a member other than a porous member may hence be used as a support member that supports a wafer. For example, JP 2006-263795A discloses a chuck table using a support member (holding portion) that includes elevations and depressions, which are regularly formed, and suction paths connected to the depressions. Further, J P 2010-87141A discloses a chuck table using a support member (holding pad) that includes a plurality of regularly formed pores and suction paths connected to the pores. These chuck tables described above each support the wafer by the support member having an upper surface at a uniform height position, thereby enabling to avoid holding the wafer in an irregularly deformed state. In addition, the depressions or pores of the support member are formed with predetermined dimensions and at predetermined intervals, so that the depressions or pores are not connected unexpectedly into large size grooves. It is hence possible to prevent an interference with the appropriate holding of the wafer due to such large size grooves.

### SUMMARY OF THE INVENTION

If a support member with depressions or pores formed in a surface thereof is used as a chuck table as described above, the chuck table is provided with a holding surface by the surface of the support member. If a wafer is then processed by a processing apparatus that includes such a chuck table, contaminant particles such as debris (processing debris) occurred through the processing of the wafer may stick the holding surface of the chuck table. In addition, the holding surface of the chuck table may be unexpectedly scratched or otherwise damaged by repeated transfer of wafers onto the chuck table.

If an abnormality occurs on the holding surface of the chuck table as described above, the wafer may not be appropriately held on the holding surface, thereby possibly causing a processing failure. The support member of the chuck table is therefore periodically replaced according to the operating conditions of the processing apparatus. Replacement of the support member may also be needed when a wafer to be processed by the processing apparatus has a different shape or size.

However, manufacture of a support member is laborious and costly. Described specifically, use of a support member having stiffness of a certain degree or higher is needed to hold a wafer in a flat state so that the support member is not readily deformed when the wafer is placed on the support member. A need therefore arises to provide a member having a certain degree of thickness as the support member, thereby imposing a heavy burden of material cost for the support member. Further, such a thick support member leads to increases in the labor and cost required for processing to form degressions or pores in the support member. If the replacement of the support member is frequently made, the burden of work to replenish replacement support members therefore increases.

With such problems in view, the present invention has as objects thereof the provision of a chuck table which enables easy and low cost replacement of a holding surface that holds a workpiece, and a laser processing apparatus including the chuck table.

In accordance with an aspect of the present invention, there is provided a chuck table for holding a workpiece under suction. The chuck table includes a base table having a suction path to be connected to a suction source, a support member that is mounted on the base table and supports the workpiece, and a protective plate disposed so as to cover an upper surface of the support member and to protect the support member. The protective plate has a plurality of through-holes that transmits a suction force from the suction source to the workpiece.

Preferably, it should be noted that the protective plate may have a porosity of 5% or higher and 35% or lower. Preferably, the base table may also include a support member suction path configured to hold the support member under suction, a protective plate suction path formed on an outer periphery side of the support member suction path and configured to hold the protective plate at an outer peripheral portion thereof under suction, and a workpiece suction path configured to hold the workpiece under suction. Preferably, the protective plate may also be formed of a transparent body. Preferably, the support member may also be formed of a transparent body.

Preferably, the support member may also be thicker at an outer peripheral portion thereof than at a central portion thereof. Preferably, the through-holes may also be formed at a higher density on an outer periphery side than on a center side of the protective plate.

In accordance with another aspect of the present invention, there is provided a laser processing apparatus including a chuck table configured to hold a workpiece under suction, a laser beam application unit configured to apply processing to the workpiece held on the chuck table by irradiating a laser beam to the workpiece, and a moving unit configured to relatively move the chuck table and the laser beam application unit. The chuck table includes a base table having a suction path connected to a suction source, a support member that is mounted on the base table and supports the workpiece, and a protective plate disposed so as to cover an upper surface of the support member and to protect the support member. The protective plate has a plurality of through-holes that transmits a suction force from the suction source to the workpiece.

In the chuck table according to the aspect of the present invention, the support member, which supports the workpiece, and the protective plate, which covers and protects the support member, are mounted on the base table. The suction force of the suction source connected to the base table is transmitted to the workpiece via the support member and the protective plate. Therefore, a member for transmitting the suction force, which is acting on the base table, to the workpiece is separated into the support member and the protective plate.

If an abnormality occurs on the holding surface of the above-described chuck table, the protective plate alone needs a replacement, but the support member needs no replacement. Further, the protective plate is supported by the support member, and therefore can hold the workpiece in a flat state even if the stiffness of the protective plate itself is low. Therefore, the protective plate can be thinned, thereby enabling to reduce the material cost of the protective plate and the labor and cost required for the processing of the protective plate. As a result, the replacement of the holding surface of the chuck table can be made easily at low cost.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a first laser processing apparatus;

FIG. 2 is a perspective view depicting a workpiece;

FIG. 3 is an exploded perspective view depicting a chuck table of the first laser processing apparatus;

FIG. 4A is a cross-sectional view depicting a protective plate of the chuck table;

FIG. 4B is an enlarged fragmentary cross-sectional view of the protective plate of FIG. 4A with shield tunnels formed therein;

FIG. 4C is a perspective view depicting one of the shield tunnels in FIG. 4B;

FIG. 5 is a cross-sectional view depicting the chuck table of FIG. 3 with the workpiece held thereon;

FIG. 6 is a cross-sectional view depicting a chuck table that includes a protective plate with a recessed portion formed therein;

FIG. 7 is a cross-sectional view depicting a chuck table including a plurality of frame holding mechanisms;

FIG. 8 is a perspective view depicting a second laser processing apparatus;

FIG. 9 is a perspective view depicting a moving unit of the second laser processing apparatus;

FIG. 10A is a cross-sectional view depicting a chuck table of the second laser processing apparatus; and

FIG. 10B is a plan view depicting the chuck table of the second laser processing apparatus.

### DETAILED DESCRIPTION OF THE PREFERRED EMBODIMENT

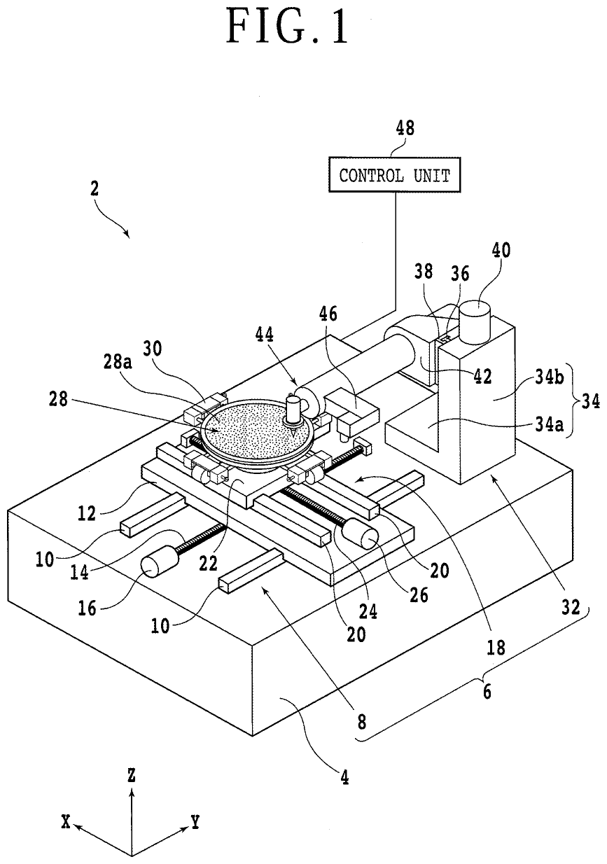

With reference to the attached drawings, an embodiment according to an aspect of the present invention will hereinafter be described. First, a description will be made about a configuration example of a processing apparatus on which a chuck table according to this embodiment can be mounted. FIG. 1 is a perspective view depicting a laser processing apparatus (a first laser processing apparatus) 2. It is to be noted that in FIG. 1, an X-axis direction (processing feed direction, first horizontal direction) and a Y-axis direction (indexing feed direction, second horizontal direction) are perpendicular to each other. It is also to be noted that, in FIG. 1, a Z-axis direction (vertical direction, up-down direction, height direction) is perpendicular to the X-axis direction and the Y-axis direction.

The laser processing apparatus 2 includes a base 4 supporting thereon individual elements that make up processing apparatus 2. The base 4 has an upper surface formed along a horizontal direction (X-Y plane direction), and a moving unit (moving mechanism) 6 is disposed on the upper surface of the base 4. The moving unit 6 includes a Y-axis moving unit (Y-axis moving mechanism) 8, an X-axis moving unit (X-axis moving mechanism) 18, and a Z-axis moving unit (Z-axis moving mechanism) 32.

The Y-axis moving unit 8 includes a pair of Y-axis guide rails 10 disposed along the Y-axis direction on the upper surface of the base 4. On the paired Y-axis guide rails 10, a plate-shaped Y-axis moving table 12 is mounted slidably along the Y-axis guide rails 10. On a side of a back surface (lower surface) of the Y-axis moving table 12, nut portions (not depicted) are disposed. A Y-axis ball screw 14 is disposed along the Y-axis direction between the paired Y-axis guide rails 10, and is maintained in threaded engagement with the nut portions. To an end portion of the Y-axis ball screw 14, a Y-axis pulse motor 16 is connected to rotate the Y-axis ball screw 14. When the Y-axis ball screw 14 is rotated by the Y-axis pulse motor 16, the Y-axis moving table 12 is moved in the Y-axis direction along the paired Y-axis guide rails 10.

The X-axis moving unit 18 includes a pair of X-axis guide rails 20 disposed along the X-axis direction on a side of a front surface (upper surface) of the Y-axis moving table 12. On the paired X-axis guide rails 20, a plate-shaped X-axis moving table 22 is mounted in a state in which it is slidable along the X-axis guide rails 20. On a side of a back surface (lower surface) of the X-axis moving table 22, nut portions (not depicted) are disposed. An X-axis ball screw 24 is disposed along the X-axis direction between the paired X-axis guide rails 20, and is maintained in threaded engagement with the nut portions. Further, to an end portion of the X-axis ball screw 24, an X-axis pulse motor 26 is connected to rotate the X-axis ball screw 24. When the X-axis ball screw 24 is rotated by the X-axis pulse motor 26, the X-axis moving table 22 is moved in the X-axis direction along the paired X-axis guide rails 20.

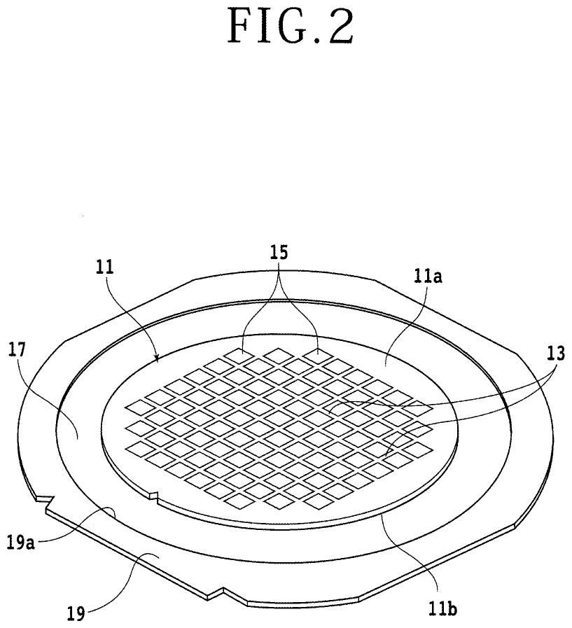

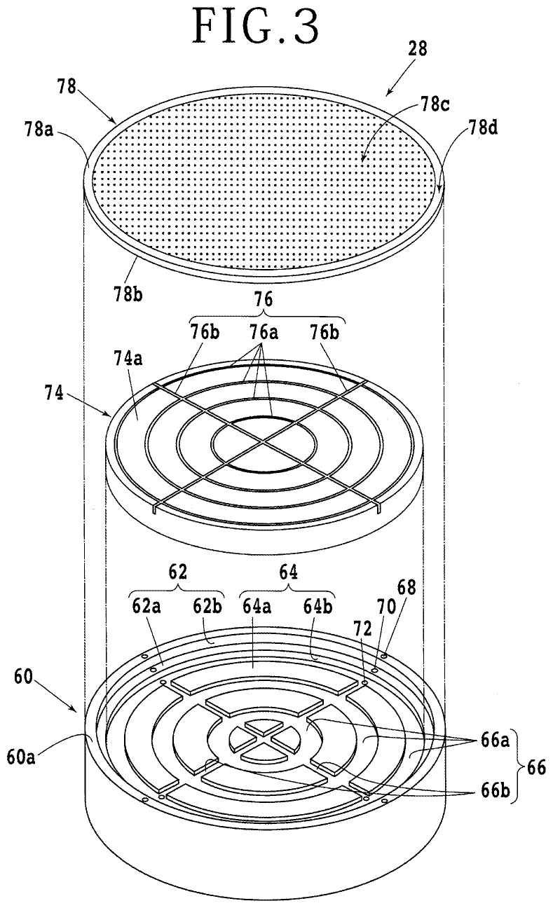

On the front surface (upper surface) of the X-axis moving table 22, a chuck table (holding table) 28 is disposed to hold a workpiece 11 (see FIG. 2) as a processing object by the laser processing apparatus 2. The upper surface of the chuck table 28 is a planar surface formed along the horizontal direction (X-Y plane direction), and makes up a holding surface 28a that holds the workpiece 11 thereon. It should be noted that details of the configuration of the chuck table 28 will be described subsequently herein (see FIGS. 3 to 7). Incidentally, around the chuck table 28, a plurality of clamps 30 is arranged to grasp and fix an annular frame 19 (see FIG. 2) that supports the workpiece 11 thereon.

FIG. 2 is a perspective view depicting the workpiece 11. The workpiece 11 is, for example, a disc-shaped wafer made from a semiconductor material such as silicon, and includes a front surface 11a and a back surface 11b, which are substantially parallel to each other. The workpiece 11 is divided into a plurality of rectangular regions by a plurality of scribe lines (hereinafter called “streets”) 13 arranged in a grid pattern so that they intersect. On a side of the front surface 11a, devices 15 such as integrated circuits (ICs), large scale integration (LSI), light emitting diodes (LEDs), or micro electro mechanical systems (MEMSs) are formed in the individual regions divided by the streets 13. By dividing the workpiece 11 along the streets 13, device chips are obtained including the devices 15 respectively.

No limitation is imposed on the kind, material, shape, construction, size, or the like of the workpiece 11. For example, the workpiece 11 may be a wafer of a desired shape and size made from a semiconductor (GaAs, InP, GaN, SiC, or the like) other than silicon, sapphire, glass, ceramics, a resin, a metal, or the like. Further, no limitation is imposed either on the type, number, shape, construction, size, arrangement, or the like of the devices 15, or none of the devices 15 may be formed on the workpiece 11.

On a side of the back surface 11b of the workpiece 11, a circular tape 17 of a diameter greater than that of the workpiece 11 is to be bonded. Employed as the tape 17 is a sheet having a film-shaped base material formed in a circular shape and an adhesive layer (glue layer) applied on the base material, or the like. The base material is made of a resin such as a polyolefin, polyvinyl chloride, or polyethylene terephthalate, while the adhesive layer is formed from an epoxy-based, acrylic, or rubber-based adhesive or the like. As an alternative, an ultraviolet curable resin that cures by application of an ultraviolet ray may also be used as the adhesive layer.

Further, the tape 17 is to be bonded at an outer peripheral portion thereof to the annular frame 19 made from a metal such as stainless steel (SUS). In a central portion of the frame 19, a circular opening 19a is formed with a diameter greater than the workpiece 11. With the workpiece 11 arranged inside the opening 19a of the frame 19, the tape 17 is bonded at a central portion thereof to the side of the back surface 11b of the workpiece 11, and at the same time is bonded at the outer peripheral portion thereof to the frame 19, whereby the workpiece 11 is supported by the frame 19 via the tape 17. When processing the workpiece 11, the workpiece 11 in a state in which it is supported by the frame 19 is held on the chuck table 28 (see FIG. 1).

When the Y-axis moving table 12 is moved along the Y-axis direction, the chuck table 28 moves along the Y-axis direction. Further, when the X-axis moving table 22 is moved along the X-axis direction, on the other hand, the chuck table 28 moves along the X-axis direction. Further, a rotary drive source (not depicted) such as a motor is connected to the chuck table 28, and rotates the chuck table 28 about a rotation axis that is substantially parallel to the Z-axis direction.

On a rear end portion of the base 4 (in rear of the Y-axis moving unit 8, the X-axis moving unit 18, and the chuck table 28), the Z-axis moving unit 32 is disposed. The Z-axis moving unit 32 includes a support structure 34 arranged on the upper surface of the base 4. The support structure 34 includes a parallelepipedal base portion 34a fixed on the base 4, and a columnar support portion 34b extending upward from an end portion of the base portion 34a. The support portion 34b has a surface (side surface) formed in a planar shape along the Z-axis direction.

On the surface of the support portion 34b, a pair of Z-axis guide rails 36 is disposed along the Z-axis direction. On the paired Z-axis guide rails 36, a plate-shaped Z-axis moving table 38 is mounted in a state in which it is slidable along the Z-axis guide rails 36. On a side of a back surface of the Z-axis moving table 38, nut portions (not depicted) are disposed. A Z-axis ball screw (not depicted) is disposed along the Z-axis direction between the paired Z-axis guide rails 36 and is maintained in threaded engagement with the nut portions. Further, to an end portion of the Z-axis ball screw, a Z-axis pulse motor 40 is connected to rotate the Z-axis ball screw. When the Z-axis ball screw is rotated by the Z-axis pulse motor 40, the Z-axis moving table 38 is moved in the Z-axis direction along the paired Z-axis guide rails 36.

On a side of a front surface of the Z-axis moving table 38, a support member 42 is fixed. The support member 42 supports some elements of a laser beam application unit 44. The laser beam application unit 44 applies a laser beam to the workpiece 11 held on the chuck table 28, and applies laser processing to the workpiece 11. Described specifically, the laser beam application unit 44 includes a laser oscillator (not depicted) such as yttrium aluminum garnet (YAG) laser or YVO₄ laser, and a condenser (not depicted) that condenses a laser oscillated from the laser oscillator. For example, the laser oscillator is disposed on the base 4, and the condenser is supported by the support member 42.

On a distal end portion of the laser beam application unit 44, an imaging unit 46 is arranged to image the workpiece 11 held on the chuck table 28, or the like. The imaging unit 46 is configured, for example, of a visible light camera including imaging sensors that receive visible light and convert it into electrical signals, an infrared light camera including imaging sensors that receive infrared light and convert it into electrical signals, or the like, and is arranged so that it is located adjacent a distal end portion of the laser beam application unit 44 in the X-axis direction. Based on an image of the workpiece 11 as acquired by imaging the workpiece 11 with the imaging unit 46, an alignment or the like is made between the chuck table 28 and the laser beam application unit 44.

When the Z-axis moving table 38 is moved in the Z-axis direction, the laser beam application unit 44 and the imaging unit 46 move in the Z-axis direction. As a consequence, an adjustment of the height position of a focal point of the laser beam applied from the laser beam application unit 44, focusing of the imaging unit 46, and the like are conducted. The Y-axis moving unit 8, the X-axis moving unit 18, and the Z-axis moving unit 32 make up the moving unit 6 that relatively moves the chuck table 28, the laser beam application unit 44, and the imaging unit 46.

The individual elements (the moving unit 6, the chuck table 28, the clamps 30, the laser beam application unit 44, the imaging unit 46, and the like) that make up the laser processing apparatus 2 are connected to a control unit (control section) 48. The control unit 48 generates control signals that control actuation of the elements of the laser processing apparatus 2, and controls operation of the laser processing apparatus 2. For example, the control unit 48 is configured of a computer, and includes an arithmetic and logic section that performs various arithmetic and logic operations needed for the operation of the laser processing apparatus 2, and a storage section in which various information (data, programs, and the like) are stored. The arithmetic and logic section is configured including a processor such as a central processing unit (CPU), while the storage section is configured including a variety of memories that make up a main storage device, an auxiliary storage device, and the like.

When processing the workpiece 11 (see FIG. 2) by the laser processing apparatus 2, the workpiece 11 is first held on the chuck table 28. Described specifically, the workpiece 11 is placed on the chuck table 28 so that the side of the back surface 11b (the side of the tape 17) faces the holding surface 28a. The frame 19 is then fixed by the clamps 30. When a negative pressure is caused to act on the holding surface 28a in this state, the workpiece 11 is held under suction on the chuck table 28 via the tape 17.

A laser beam is next applied from the laser beam application unit 44 toward the workpiece 11, whereby laser processing is applied to the workpiece 11. The wavelength of the laser beam is set, for example, so that at least a portion of the laser beam is absorbed in the workpiece 11. Further, other application conditions (power, spot diameter, repetition frequency, and the like) of the laser beam are appropriately set so that the workpiece 11 is processed through ablation in regions where the laser beam is applied.

When the chuck table 28 is moved in the X-axis direction with the focal point of the laser beam positioned on the front surface 11a of the workpiece 11 or inside the workpiece 11, the laser beam having absorption in the workpiece 11 is applied to the workpiece 11 along desired one of the streets 13. As a result, a linear groove (laser processed groove) is formed along the desired street 13 in the workpiece 11. The workpiece 11 can be divided along all the streets 13, for example, by forming grooves along all the streets 13, respectively, from the front surface 11a to the back surface 11b of the workpiece 11. As an alternative, the workpiece 11 can be also divided along all the streets 13 by forming grooves, which have a depth smaller than the thickness of the workpiece 11, along all the streets 13 on the side of the front surface 11a of the workpiece 11 and then griding the workpiece 11 on the side of the back surface 11b thereof to expose the grooves on the side of the back surface 11b of the workpiece 11. As a consequence, a plurality of device chips is manufactured including the devices 15, respectively.

When applying laser processing to the workpiece 11 by the laser beam application unit 44 as described above, the workpiece 11 is held on the chuck table 28. FIG. 3 is an exploded perspective view depicting the chuck table 28 with the workpiece 11 held thereon.

The chuck table 28 includes a cylindrical base table (base) 60 made from glass, ceramics, a metal, a resin, or the like. In a central portion of the base table 60, a cylindrical first groove (first recessed portion) 62 is formed on a side of an upper surface 60a. The first groove 62 includes a circular bottom surface 62a and an annular side surface (side wall) 62b. In the central portion of the base table 60, a cylindrical second groove (second recessed portion) 64 having a smaller diameter than the first groove 62 is also formed on a side of the bottom surface 62a of the first groove 62. The second groove 64 includes a circular bottom surface 64a and an annular side surface (side wall) 64b.

On a side of the bottom surface 64a of the second groove 64, third grooves (third recessed portions) 66 are formed. The third grooves 66 include, for example, a plurality of annular grooves 66a, specifically three annular grooves 66a formed concentrically, and a plurality of grooves 66b, specifically two grooves 66b formed linearly along a radial direction of the base table 60. The grooves 66b are formed extending diametrically across the bottom surface 64a of the second groove 64 so that the grooves 66b intersect each other, and the grooves 66b are connected together at a central portion of the second groove 64. The grooves 66b also intersect the grooves 66a, respectively, and are connected with the grooves 66a in the regions of intersections.

In addition, the base table 60 also includes a plurality of suction paths to be connected to a suction source. Described specifically, the base table 60 includes a plurality of suction paths (protective plate suction paths) 68 opening in the upper surface 60a of the base table 60, a plurality of suction paths (workpiece suction paths) 70 opening in the bottom surface 62a of the first groove 62, and a plurality of suction paths (support member suction paths) 72 opening in a bottom surface of the third grooves 66, specifically the radially outermost annular groove 66a. The suction paths 68 are formed in the base table 60 on an outer periphery side of the suction paths 70. On the other hand, the suction paths 70 are formed in the base table 60 on an outer periphery side of the suction paths 72. The suction paths 68 are arranged, for example, at substantially equal intervals along the direction of a periphery of the base table 60, and so the suction paths 70 and the suction paths 72. For example, it is to be noted that no limitation is imposed on the number or arrangement of the suction paths 68, 70, and 72 although the base table 60 having four suction paths 68, four suction paths 70, and four suction paths 72 is depicted in FIG. 3.

On the base table 60, a support member 74 is mounted to support the workpiece 11 (see FIG. 2). The support member 74 is formed, for example, in a disc shape having a thickness of approximately 7 mm or so. On a side of an upper surface 74a of the support member 74, grooves (depressions) 76 are formed. The grooves 76 include, for example, a plurality of annular first grooves 76a formed concentrically, and a plurality of second grooves 76b formed linearly along a radial direction of the support member 74. The second grooves 76b are formed extending diametrically across the upper surface 74a of the support member 74 so that they intersect each other, and the second grooves 76b are connected together at a central portion of the support member 74. It is to be noted that opposite ends of the second grooves 76b are exposed at a side surface (outer peripheral surface) of the support member 74. The second grooves 76b also intersect the first grooves 76a, respectively, and are connected with the first grooves 76a in the regions of intersections.

The support member 74 is formed so that its diameter becomes substantially equal to that of the second groove 64 of the base table 60, and is fitted in the second groove 64. Here, the bottom surface 64a of the second groove 64 functions as a support surface that supports the support member 74 on a side of a lower surface thereof. Further, the support member 74 has a thickness substantially equal to a difference in height between the upper surface 60a of the base table 60 and the bottom surface 64a of the second groove 64. When the support member 74 is inserted into the second groove 64, the upper surface 60a of the base table 60 and the upper surface 74a of the support member 74 therefore lie on substantially the same plane.

It should be noted that no limitation is imposed on the material of the support member 74. The support member 74 is formed, for example, of a transparent body of glass (quartz glass, borosilicate glass, soda lime glass, alkali-free glass, or the like), sapphire, calcium fluoride, lithium fluoride, magnesium fluoride, or the like. As the material of the support member 74, low melting point glass having a lower melting point than soda lime glass can also be used. Further, no limitation is imposed on the shape, size, number, position, intervals, or the like of the grooves 76.

On the support member 74 mounted on the base table 60, a protective plate 78 is disposed to protect the support member 74. For example, the protective plate 78 is formed in a disc shape and includes an upper surface (front surface) 78a and a lower surface (back surface) 78b, which are substantially parallel to each other. The protective plate 78 is formed so that its diameter becomes greater than that of the first groove 62 of the base table 60, and is disposed so as to cover the upper surface 60a of the base table 60 and the upper surface 74a of the support member 74.

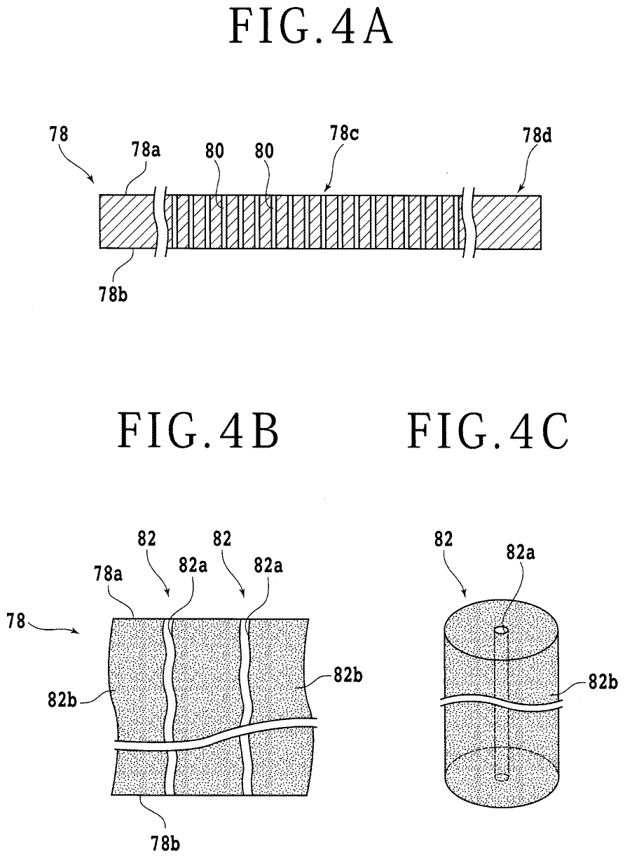

FIG. 4A is a cross-sectional view depicting the protective plate 78. The protective plate 78 has a circular central portion (central region) 78c including a center of the protective plate 78, and an annular outer peripheral portion (outer peripheral region) 78d including an outer peripheral edge of the protective plate 78 and surrounding the central portion 78c. In the central portion 78c of the protective plate 78, a plurality of through-holes 80 is formed extending in a thickness direction of the protective plate 78. The through-holes 80 are formed, for example, in a columnar shape, and are exposed at the upper surface 78a and the lower surface 78b of the protective plate 78. In the outer peripheral portion 78d of the protective plate 78, on the other hand, no through-holes 80 are formed.

It should be noted that no limitation is imposed on the material of the protective plate 78. The protective plate 78 is formed, for example, of a transparent body of glass (quartz glass, borosilicate glass, soda lime glass, alkali-free glass, or the like), sapphire, calcium fluoride, lithium fluoride, magnesium fluoride, or the like. As the material of the protective plate 78, low melting point glass having a lower melting point than that of soda lime glass can also be used. It is particularly preferred to use glass (borosilicate glass, soda lime glass, alkali-free glass, or the like) other than quartz glass for the support member 74 and the protective plate 78. If this is the case, the processing (the formation or the like of the grooves 76 and the through-holes 80) of the support member 74 and the protective plate 78 can be easily conducted while reducing the material cost of the support member 74 and the protective plate 78.

Further, no limitation is imposed either on the size, number, position, positions, intervals, or the like of the through-holes 80. For example, the through-holes 80 each have a diameter set at 500 μm or smaller, preferably 100 μm or smaller. Described specifically, the diameter of the through-holes 80 can be set at 5 μm or greater and 40 μm or smaller, with 10 μm or greater and 15 μm or smaller being preferred. No limitation is imposed either on the shape of the through-holes 80. For example, the through-holes 80 may be formed in a quadrilateral prismatic shape. If this is the case, the through-holes 80 have a width set at 500 μm or smaller, preferably 100 μm or smaller. Described more specifically, the width of the through-holes 80 can be set at 5 μm or greater and 40 μm or smaller, with 10 μm or greater and 15 μm or smaller being preferred.

Further, no limitation is imposed on a method for the formation of the through-holes 80. For example, filament-shaped pores called “shield tunnels” are formed in the protective plate 78 by application of a laser beam. FIG. 4B is an enlarged fragmentary cross-sectional view depicting the protective plate 78 with shield tunnels 82 formed therein, and FIG. 4C is a perspective view depicting one of the shield tunnels 82.

When the laser beam is applied and scanned over the protective plate 78 with a focal point of the laser beam positioned inside the protective plate 78, the shield tunnels 82 are formed at predetermined intervals along a scanning direction of the laser beam. The shield tunnels 82 each include a fine hole 82a formed along the thickness direction of the protective plate 78, and an amorphous region 82b surrounding the fine hole 82a. The shield tunnels 82 are each formed over the entire region in the thickness direction of the protective plate 78. As a result, the fine holes 82a exposed at the upper surface 78a and the lower surface 78b of the protective plate 78 are formed. Further, the amorphous regions 82b themselves of the adjacent shield tunnels 82 are connected to each other.

Application conditions for the laser beam are set as desired so that the shield tunnels 82 are appropriately formed in the protective plate 78. If the protective plate 78 is made from glass (borosilicate glass), for example, the application conditions for the laser beam can be set as follows.

Light source: YAG pulse laser

Wavelength: 1,064 nm

Energy: 40 μJ

Repetition frequency: 10 kHz

Processing feed rate: 100 mm/s

The shield tunnels 82 are formed at predetermined intervals over the entire region of the central portion 78c of the protective plate 78. The fine holes 82a of the shield tunnels 82 are used as the through-holes 80 (see FIG. 4A) of the protective plate 78. However, no limitation is imposed on a method for the formation of the through-holes 80.

By applying etching to the protective plate 78, for example, through-holes 80 of a desired size can be formed at desired intervals. In this case, the through-holes 80 may be formed using a member, which is made from glass ceramics (crystallized glass), as the protective plate 78, and processing the protective plate 78 through selective etching. In addition, processing such as ion doping may be applied to a region (the central portion 78c), in which the through-holes 80 are to be formed, before applying etching to the protective plate 78, so that the etching is facilitated to proceed locally in the region. As a further alternative, the protective plate 78 may be fabricated by pouring the material of the protective plate 78 into a predetermined mold and firing the material. In this case, the mold is internally provided with a plurality of columnar members (pin-shaped projections) corresponding to the through-holes 80. When the material of the protective plate 78 is fired using this mold, the protective plate 78 is fabricated with the through-holes 80.

As described above, the protective plate 78 can be easily fabricated by simply forming the through-holes 80 in a plate-shaped member. Therefore, the structure and fabrication steps of the protective plate 78 are extremely simple, and the labor and cost required for the fabrication of the protective plate 78 are small. Incidentally, preferably, the protective plate 78 is formed thinner than the support member 74. For example, the protective plate 78 is set to have a thickness of 0.2 mm or greater and 0.3 mm or smaller. If the protective plate 78 is thin, the material cost of the protective plate 78 is reduced, and further the formation of the through-holes 80 in the protective plate 78 is facilitated.

As depicted in FIG. 3, the protective plate 78 is disposed over the base table 60 and the support member 74 so that the central portion 78c covers the upper surface 74a of the support member 74 and the outer peripheral portion 78d covers the upper surface 60a of the base table 60. Therefore, the protective plate 78 is supported by the support member 74, and the suction paths 68 formed in the base table 60 are covered by the protective plate 78. It is to be noted that no limitation is imposed on the diameter of the protective plate 78 insofar as the suction paths 68 can be covered by the protective plate 78. The protective plate 78 hence has a high degree of dimensional freedom. The workpiece 11 (see FIG. 2) is then placed on the protective plate 78. In other words, the workpiece 11 is supported on the support member 74 via the protective plate 78. The upper surface 78a of the protective plate 78 corresponds to the holding surface 28a (see FIG. 1) of the chuck table 28.

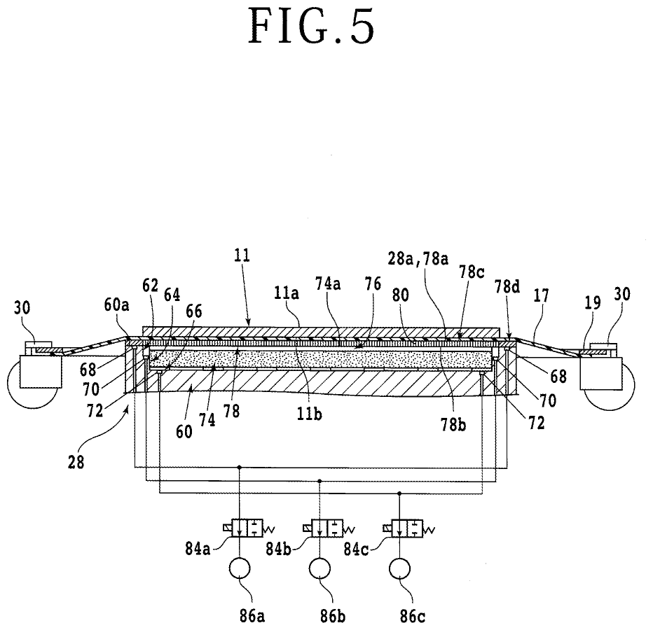

FIG. 5 is a cross-sectional view depicting the chuck table 28 with the workpiece 11 held thereon. The suction paths 68, 70, and 72 formed in the base table 60 are connected to suction sources, respectively. Described specifically, the suction paths 68 are used to hold the outer peripheral portion 78d of the protective plate 78 under suction and are connected to a suction source 86a via a valve 84a. The suction paths 70 are used to hold the workpiece 11 under suction and are connected to a suction source 86b via a valve 84b. Further, the suction paths 72 are used to hold the support member 74 under suction, and are connected to a suction source 86c via a valve 84c. As the valves 84a, 84b, and 84c, solenoid valves are used, for example, and the control unit 48 (see FIG. 1) controls on/off of the valves 84a, 84b, and 84c. As the suction sources 86a, 86b, and 86c, on the other hand, ejectors are used, for example, and the control unit 48 controls operations of the suction sources 86a, 86b, and 86c.

When the valve 84c is opened with the support member 74 fitted in the second groove 64 of the base table 60, a suction force (negative pressure) of the suction source 86c acts on an inside (third grooves 66) of the base table 60. As a consequence, the support member 74 is held under suction in the base table 60 and is fixed on the base table 60.

When the valve 84a is opened with the protective plate 78 arranged on the base table 60 and the support member 74, on the other hand, a suction force (negative pressure) of the suction source 86a acts on the outer peripheral portion 78d, in which no through-holes 80 are formed, of the protective plate 78. As a consequence, the protective plate 78 is held under suction on the base table 60 and the support member 74, and is fixed on the base table 60.

The workpiece 11 is placed via the tape 17 on the protective plate 78 fixed on the base table 60. Further, the frame 19 with the workpiece 11 supported thereon is grasped by the clamps 30. When the valve 84b is opened in the above-described state, the first groove 62 of the base table 60, the first groove 62 being covered by the support member 74 and the protective plate 78, is depressurized by the suction force (negative pressure) of the suction source 86b. Similarly, the insides of the grooves 76 of the support member 74, the grooves 76 being connected with the first groove 62, are also depressurized. As a result, the suction force acts on the upper surface 78a of the protective plate 78 via the through-holes 80 arranged in a region where the through-holes 80 overlap the first groove 62 or the grooves 76. In other words, the through-holes 80 function as flow paths that transmit the suction force from the suction source 86b to the workpiece 11. As a consequence, the workpiece 11 is held under suction on the chuck table 28 via the tape 17.

It should be noted that the percentage of the total volume of the through-holes 80 in the volume of the whole protective plate 78 (the porosity of the protective plate 78) is set so that a sufficient suction force acts on the workpiece 11 and the mechanical strength of the protective plate 78 is maintained at a certain level or higher. For example, the porosity of the protective plate 78 is set at 5% or higher and 35% or lower.

A laser beam is then applied from the laser beam application unit 44 depicted in FIG. 1 toward the workpiece 11, whereby laser processing is applied to the workpiece 11. Upon completion of the processing of the workpiece 11, the valve 84b is closed to release the suction of the workpiece 11, and the workpiece 11 is transferred from the holding surface 28a of the chuck table 28.

Incidentally, while the workpiece 11 is held on the chuck table 28, the tape 17 may come into firm contact with the upper surface 78a of the protective plate 78 depending on the material of the tape 17. Further, when laser processing is applied to the workpiece 11, the laser beam may also be applied to a part of the tape 17 at portions thereof located outside an outer peripheral edge of the workpiece 11, so that the tape 17 may melt and adhere to the upper surface 78a of the protective plate 78. In such cases, the workpiece 11 becomes hardly separable from the protective plate 78, thereby potentially making it difficult to appropriately transfer the workpiece 11 from the holding surface 28a of the chuck table 28.

Therefore, the through-holes 80 are preferably formed at a higher density on an outer periphery side than on a center side of the protective plate 78. This enables to reduce the area of contact between the tape 17 and the upper surface 78a of the protective plate 78 in a vicinity of an outer peripheral portion of the workpiece 11. As a result, when transferring the workpiece 11 from the chuck table 28, the tape 17 is facilitated to separate from the upper surface 78a of the protective plate 78 so that the workpiece 11 is appropriately transferred. Described specifically, the through-holes 80 are formed so that they have a smaller diameter in a region (first region) located at distances in a predetermined range from the center of the protective plate 78 than in a region (second region) on an outer side of the first region. If this is the case, for example, the through-holes 80 to be formed in the first region can be set to have a diameter of smaller than 100 μm, while the through-holes 80 to be formed in the second region can be set to have a diameter of 100 μm or greater and 500 μm or smaller.

Incidentally, when the workpiece 11 is processed by the laser beam application unit 44, contaminant particles such as debris (processing debris) occurred through the processing of the workpiece 11 sticks. For example, the laser beam may be applied not only to the workpiece 11 but also to the tape 17 during the processing of the workpiece 11, whereby the tape 17 may be melted and the resulting melt may stick the holding surface 28a. Further, the laser beam may be applied to the holding surface 28a through the workpiece 11 and the tape 17, whereby the holding surface 28a may be unexpectedly processed. Furthermore, the holding surface 28a may be unexpectedly scratched or otherwise damaged by repeated transfer of workpieces 11 onto the chuck table 28. If such an inconvenience occurs on the holding surface 28a of the chuck table 28, a need then arises for the replacement of the member that makes up the holding surface 28a.

Here it is to be remembered that, in the chuck table 28 in this embodiment, a member for transmitting the suction force, which is acting on the base table 60, to the workpiece 11 is separated into the support member 74 and the protective plate 78. Upon occurrence of an abnormality on the holding surface 28a of the chuck table 28, only the protective plate 78 needs a replacement, and the support member 74 needs no replacement. Further, the protective plate 78 is supported by the support member 74, so that the workpiece 11 can be held in a flat state by the protective plate 78 even if the stiffness of the protective plate 78 itself is low. The protective plate 78 can therefore be thinned, thereby making it possible to reduce the material cost of the protective plate 78 and the labor and cost required for the processing of the protective plate 78. As a result, the replacement of the holding surface 28a of the chuck table 28 can be made easily at low cost.

The replacement of the protective plate 78 can be easily made by controlling the on/off of the valve 84a. Described specifically, the valve 84a is first closed with the valve 84c held open. As a consequence, the suction of the protective plate 78, which is to be replaced, is released while the holding of the support member 74 under suction is maintained. The protective plate 78 to be replaced is then detached from the base table 60, and a replacement protective plate 78 (a new protective plate 78) is then arranged on the base table 60, followed by reopening of the valve 84a. As a result, the replacement protective plate 78 is held under suction, and is fixed on the base table 60.

The foregoing description is directed to the example in which the protective plate 78 is planar, and no limitation is imposed on the shape of the protective plate 78. For example, the protective plate 78 may be formed so that it has a recessed portion in the central portion 78c and the outer peripheral portion 78d becomes thicker than the central portion 78c.

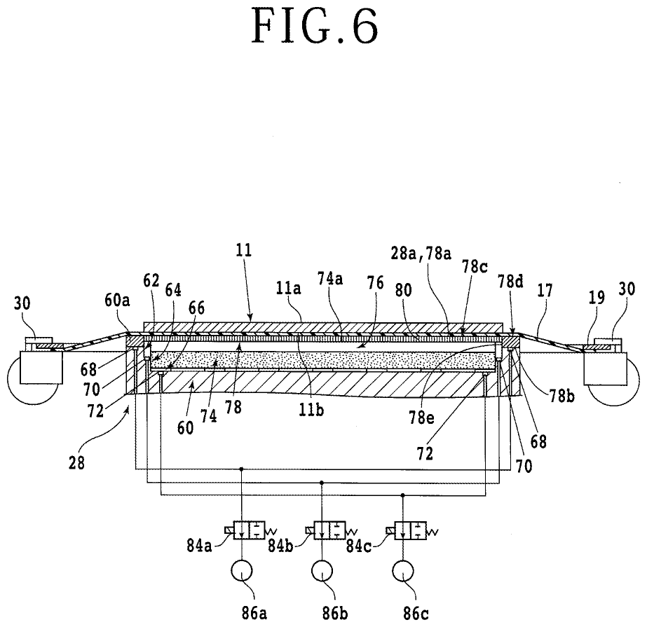

FIG. 6 is a cross-sectional view depicting a chuck table 28 that includes a protective plate 78 with a columnar recessed portion 78e formed therein. The cylindrical recessed portion 78e is formed on a side of a lower surface 78b of a central portion 78c of the protective plate 78 depicted in FIG. 6. The recessed portion 78e has a diameter equal to or greater than that of a support member 74. The support member 74 depicted in FIG. 6 is formed so that its upper surface 74a protrudes from the upper surface 60a of the base table 60.

The protective plate 78 is arranged on the support member 74 so that the support member 74 is fitted on the side of the upper surface 74a thereof in the recessed portion 78e. The difference in height between the upper surface 60a of the base table 60 and the upper surface 74a of the support member 74 (the amount of protrusion of the support member 74) is set to be substantially equal to the depth of the recessed portion 78e. Therefore, when the protective plate 78 is arranged on the support member 74, the central portion 78c (a top surface, in other words, a ceiling surface of the recessed portion 78e) of the protective plate 78 is supported by the support member 74, and at the same time the protective plate 78 is supported at an outer peripheral portion 78d thereof by the upper surface 60a of the base table 60.

When the recessed portion 78e is formed in the central portion 78c of the protective plate 78, the central portion 78c is thinned, thereby facilitating the formation of the through-holes 80 in the central portion 78c. In the outer peripheral portion 78d of the protective plate 78, on the other hand, the recessed portion 78e is not formed so that the outer peripheral portion 78d remains in a thick state. The stiffness of the protective plate 78 is therefore maintained by the thick outer peripheral portion 78d so that the protective plate 78 still remains to be resistant to deformation. Therefore, the outer peripheral portion 78d functions as a reinforcement portion that reinforces the protective plate 78. As a consequence, the protective plate 78 can be prevented from deformation and damage when it is handled.

Details of the configuration of the chuck table 28 can be changed as needed. For example, the chuck table 28 may include mechanisms that hold under suction the frame 19 with the workpiece 11 supported thereon. If this is the case, the clamps 30 (see FIGS. 1 and 5) can be omitted.

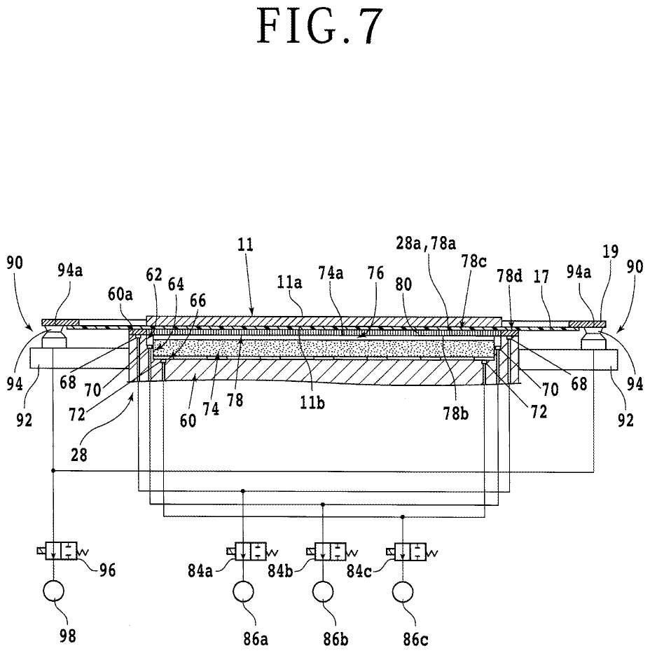

FIG. 7 is a cross-sectional view depicting a chuck table 28 including a plurality of frame holding mechanisms (frame holding portions) 90. On a side surface (outer peripheral surface) of the base table 60, the frame holding mechanisms 90 are fixed to hold the frame 19. For example, four frame holding mechanisms 90 are arranged at substantially equal intervals along the direction of the periphery of the base table 60. The frame holding mechanisms 90 each include a base 92 fixed on the base table 60, and a suction pad 94 disposed on the base 92. The suction pads 94 are made, for example, from rubber, a resin, or the like. Further, upper surfaces of the suction pads 94 are formed along the horizontal direction, and make up holding surfaces 94a that hold the frame 19 under suction. The holding surfaces 94a are connected to a suction source 98 such as an ejector via flow paths (not depicted), which are formed inside the corresponding suction pads 94, and a valve 96 such as a solenoid valve.

When the workpiece 11 is placed on the chuck table 28, the frame 19 is placed on the holding surfaces 94a of the suction pads 94 at the same time. When the valve 96 is opened in this state, a suction force (negative pressure) of the suction source 98 acts on the holding surfaces 94a so that the frame 19 is held under suction by the suction pads 94.

It is to be noted that the suction paths 68 and the suction paths 72 may be connected to a common suction source (one of the suction source 86a or the suction source 86c) via a common valve (the corresponding one of the valve 84a or the valve 84c). In this case, the holding of the support member 74 under suction and the holding of the protective plate 78 under suction are performed at the same timing in an interlocked manner. In addition, the suction paths 70 and the suction pads 94 may be connected to a common suction source (one of the suction source 86b or the suction source 98) via a common valve (the corresponding one of the valve 84b or the valve 96). In this case, the holding of the workpiece 11 and the tape 17 under suction and the holding of the frame 19 under suction are performed at the same timing in an interlocked manner.

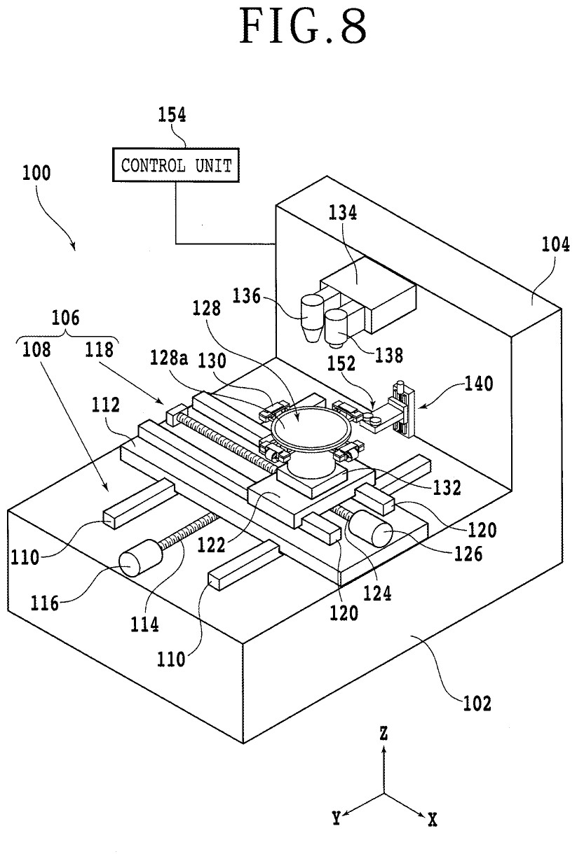

The processing apparatus on which the chuck table according to this embodiment is to be mounted is not limited to the above-described laser processing apparatus (see FIG. 1). FIG. 8 is a perspective view depicting a laser processing apparatus (second laser processing apparatus) that is different in configuration from the laser processing apparatus 2. It is to be noted that, in FIG. 8, an X-axis direction (processing feed direction, first horizontal direction) and a Y-axis direction (indexing feed direction, second horizontal direction) are perpendicular to each other. Further, a Z-axis direction (vertical direction, up-down direction, height direction) is perpendicular to the X-axis direction and the Y-axis direction.

The laser processing apparatus 100 includes a base 102 supporting thereon individual elements that make up processing apparatus 100. The base 102 has an upper surface formed along a horizontal direction (X-Y plane direction), and a parallelepipedal support structure 104 is disposed along the Z-axis direction on a rear end portion of the base 102. In addition, a moving unit (moving mechanism) 106 is disposed on the upper surface of the base 102. The moving unit 106 includes a Y-axis moving unit (Y-axis moving mechanism) 108 and an X-axis moving unit (X-axis moving mechanism) 118.

The Y-axis moving unit 108 and the X-axis moving unit 118 have configurations which are similar to those of the Y-axis moving unit 8 and the X-axis moving unit 18, respectively, of the laser processing apparatus 2 (see FIG. 1). Described specifically, the Y-axis moving unit 108 includes a pair of Y-axis guide rails 110, a Y-axis moving table 112, a Y-axis ball screw 114, and a Y-axis pulse motor 116. On the other hand, the X-axis moving unit 118 includes a pair of X-axis guide rails 120, an X-axis moving table 122, an X-axis ball screw 124, and an X-axis pulse motor 126.

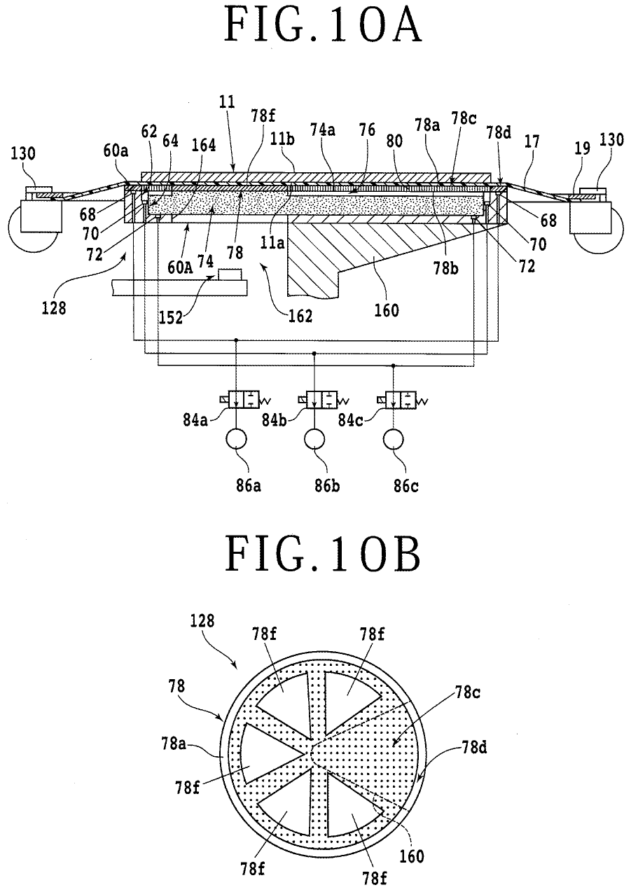

On the front surface (upper surface) of the X-axis moving table 122, a chuck table (holding table) 128 is disposed to hold a workpiece 11 (see FIG. 2) as a processing object by the laser processing apparatus 100. The upper surface of the chuck table 128 makes up a holding surface 128a that holds the workpiece 11. It should be noted that details of the configuration of the chuck table 128 will be described subsequently herein (see FIGS. 10A and 10B).

Around the chuck table 128, a plurality of clamps 130 is arranged to grasp and fix an annular frame 19 (see FIG. 2) that supports the workpiece 11. Incidentally, instead of the clamps 130, frame holding mechanisms (see the frame holding mechanisms 90 in FIG. 7) may be used to hold the frame 19 under suction.

When the Y-axis moving table 112 is moved along the Y-axis direction, the chuck table 128 moves along the Y-axis direction. Further, when the X-axis moving table 122 is moved along the X-axis direction, on the other hand, the chuck table 128 moves along the X-axis direction.

On a side below the chuck table 128, a rotating unit (rotating mechanism) 132 is disposed. The rotating unit 132 is disposed on the X-axis moving table 122 of the moving unit 106, and the chuck table 128 is connected on a side of its lower end to the rotating unit 132. The rotating unit 132 includes a rotary drive source such as a motor, and rotates the chuck table 128 about a rotation axis that is substantially parallel to the Z-axis direction. As a consequence, the angle (direction) of the chuck table 128 in the horizontal direction is controlled.

The laser processing apparatus 100 also includes a columnar support arm 134 extending forward from a side of a front surface of the support structure 104. On a distal end portion of the support arm 134, a laser beam application unit 136 is fixed to apply a laser beam to the workpiece 11 held on the chuck table 128. It is to be noted that the laser beam application unit 136 has a configuration similar to that of the laser beam application unit 44 (see FIG. 1) of the laser processing apparatus 2. On the distal end portion of the support arm 134, an imaging unit 138 is also fixed at a position adjacent the laser beam application unit 136 to image from above the workpiece 11 held on the chuck table 128. The imaging unit 138 is configured, for example, of a visible light camera, an infrared light camera, or the like. Incidentally, to the support arm 134, a moving unit (moving mechanism, not depicted) may be connected to move the support arm 134 along the Z-axis direction. If this is the case, the height position of the laser beam application unit 136 and imaging unit 138 is controlled by the moving unit.

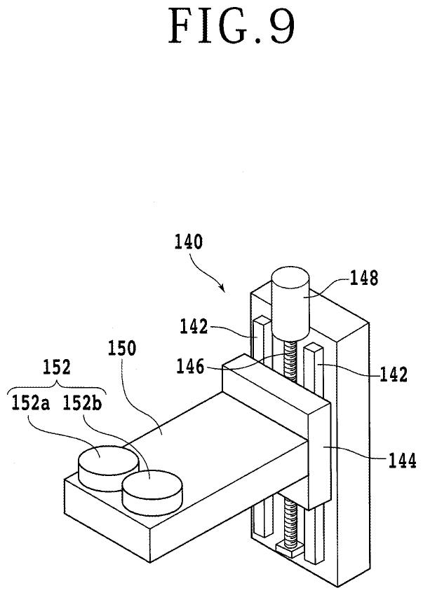

Disposed below the support arm 134 is a Z-axis moving unit (Z-axis moving mechanism) 140 fixed on the side of the front surface of the support structure 104. FIG. 9 is a perspective view depicting the moving unit 140. The moving unit 140 includes a pair of Z-axis guide rails 142 disposed along the Z-axis direction. On the paired Z-axis guide rails 142, a plate-shaped Z-axis moving plate 144 is mounted in a state in which it is slidable along the Z-axis guide rails 142. On a side of a back surface of the Z-axis moving plate 144, nut portions (not depicted) are disposed. A Z-axis ball screw 146 is disposed along the Z-axis direction between the paired Z-axis guide rails 142 and is maintained in threaded engagement with the nut portions. Further, to an end portion of the Z-axis ball screw 146, a Z-axis pulse motor 148 is connected to rotate the Z-axis ball screw 146. When the Z-axis ball screw 146 is rotated by the Z-axis pulse motor 148, the Z-axis moving plate 144 moves in the Z-axis direction along the paired Z-axis guide rails 142.

On a side of a front surface of the Z-axis moving plate 144, a columnar support arm 150 is fixed extending forward from the Z-axis moving plate 144. Further, on a side of an upper surface of a distal end portion (front end portion) of the support arm 150, an imaging unit 152 is arranged to image from below the workpiece 11 supported on the chuck table 128. The imaging unit 152 includes, for example, a pair of cameras 152a and 152b having magnifications different from each other. The imaging unit 152 may make imaging using one of the paired cameras 152a and 152b, or may make imaging using both of them. As the cameras 152a and 152b, visible light cameras or infrared light cameras are used, for example. The moving unit 140 moves the imaging unit 152 along the Z-axis direction. As a consequence, the height position of the imaging unit 152 is controlled to perform focusing and an imaging range adjustment of the cameras 152a and 152b.

The individual elements (the moving unit 106, the chuck table 128, the clamps 130, the rotating unit 132, the laser beam application unit 136, the imaging unit 138, the moving unit 140, the imaging unit 152, and the like) that make up the laser processing apparatus 100 are connected to a control unit (control section) 154. The control unit 154 generates control signals that control actuation of the elements of the laser processing apparatus 100, and controls operation of the laser processing apparatus 100. Similarly to the control unit (see FIG. 1) of the laser processing apparatus 2, the control unit 154 is configured of a computer, for example.

By the imaging unit 138 arranged above the chuck table 128 and the imaging unit 152 arranged below the chuck table 128, the laser processing apparatus 100 can image the workpiece 11 held on the chuck table 128. Therefore, an image of the side of the front surface of the workpiece 11 is acquired by the imaging unit 138, and an image of the side of the back surface of the workpiece 11 is acquired by the imaging unit 152.

FIG. 10A is a cross-sectional view depicting the chuck table 128, and FIG. 10B is a plan view depicting a protective plate 78 of the chuck table 128. It is to be noted that the configuration of the chuck table 128 is similar to that of the chuck table 28 (see FIGS. 3 to 7) except for the matters which will be described hereinafter.

The chuck table 128 holds the workpiece 11 via the tape 17. Incidentally, in FIG. 10A, the tape 17 is bonded to a side of a front surface 11a (a side of the devices 15, see FIG. 2) of the workpiece 11, and the workpiece 11 is placed so that the side of the front surface 11a faces the chuck table 128.

Similarly to the chuck table 28 (see FIGS. 3 and 5), the chuck table 128 includes a support member 74 and a protective plate 78, although the support member 74 and the protective plate 78 are formed of transparent bodies. The chuck table 128 also includes a base table 60A, the configuration of which is partly different from that of the base table 60 (see FIGS. 3 and 5).

Similarly to the base table 60, the base table 60A includes an upper surface 60a, a first groove 62, a second groove 64, and suction paths 68, 70, and 72. However, the base table 60A is not provided with third grooves 66 (see FIGS. 3 and 5), and the support member 74 is supported by a bottom surface of the second groove 64. Further, the suction paths 72 are formed to open in the bottom surface of the second groove 64. The support member 74 is fixed on the base table 60A under a suction force of a suction source 86c, which acts on a side of a lower surface of the support member 74 via the valve 84c and the suction paths 72.

On a side of a lower surface of the base table 60A, a table support member 160 is connected to support the base table 60A. The table support member 160 is arranged to overlap only a portion of the base table 60A, and supports the base table 60A at the portion thereof. The table support member 160 has an upper surface formed, for example, in a sector shape, and supports the base table 60A in a sector region thereof extending from a central portion to an outer peripheral portion thereof. The table support member 160 is connected on a side of a lower end thereof to the rotating unit 132 (see FIG. 8).

On a side below the base table 60A, a region (space) 162 is left unoccupied. The region 162 overlaps the base table 60A but does not overlap the table support member 160. Through the base table 60A, an opening 164 is formed in a region overlapping the region 162. The opening 164 extends from the bottom surface 64a of the second groove 64 to the lower surface of the base table 60A. Inside the opening 164, the support member 74 is downwardly exposed on the side of the lower surface thereof.

Through control of the position of the chuck table 128 by the moving unit 106 (see FIG. 8), the imaging unit 152 is positioned right below the opening 164 of the base table 60A. The imaging unit 152 then images the side of the front surface 11a of the workpiece 11 through the opening 164 of the base table 60A and the support member 74 and protective plate 78 formed of the transparent bodies, respectively.

It should be noted that the materials of the support member 74 and protective plate 78 are selected as desired according to the type of the imaging unit 152. If the imaging unit 152 is configured of a visible light camera, for example, the support member 74 and the protective plate 78 are formed of members through which visible light transmits. Further, if the imaging unit 152 is configured of an infrared light camera, on the other hand, the support member 74 and the protective plate 78 are formed of members through which infrared light transmits.

The use of the above-described chuck table 128 enables to image a pattern of the devices 15 (see FIG. 2) or the like formed on the side of the front surface 11a of the workpiece 11 even when the workpiece 11 is held on the side of the front surface 11a thereof on the chuck table 128. This enables to perform an alignment or the like between the workpiece 11 and the laser beam application unit 136 through use of a pattern on the side of the front surface 11a of the workpiece 11 as a reference.

Incidentally, preferably, the support member 74 is not provided with grooves 76 in a region where the support member 74 overlaps the opening 164 of the base table 60A (see FIG. 10A). Also preferably, the protective plate 78 is not provided with through-holes 80 in a plurality of regions 78f (see FIGS. 10A and 10B) where the protective plate 78 overlaps the opening 164 of the base table 60A. When imaging the workpiece 11 by the imaging unit 152, these enable to avoid an interference with the imaging by the grooves 76 and/or through-holes 80 and to acquire a clear image of the workpiece 11.

Nonetheless, through-holes 80 can be regularly formed in the region of the protective plate 78, where the protective plate 78 overlaps the opening 164 of the base table 60A. If this is the case, image processing is applied to an image acquired by the imaging unit 152 so that an image in which the through-holes 80 are not displayed or an image in which the through-holes 80 are displayed inconspicuously is formed. Further, even if through-holes 80 exist in the region of the protective plate 78, where the protective plate 78 overlaps the opening 164 of the base table 60A, the pattern on the side of the front surface 11a of the workpiece 11 may still be observable if the through-holes 80 have a size smaller than the pixel size of the imaging unit 152, because such small through-holes 80 hardly appear in an image acquired by the imaging unit 152.

Further, the foregoing description is directed to the chuck tables 28 and 128 mounted on the laser processing apparatuses 2 and 100, respectively. However, the chuck tables according to this embodiment can also be mounted on processing apparatuses other than laser processing apparatuses. Examples of such other processing apparatuses include cutting apparatuses and the like, each of which includes a cutting unit that cuts a workpiece 11 by an annular cutting blade. For example, the workpiece 11 can be divided along streets 13 (see FIG. 2) by a cutting apparatus with one of the chuck tables according to this embodiment included therein. As a consequence, a plurality of device chips with devices 15 (see FIG. 2) included therein, respectively, is manufactured.

Incidentally, if the workpiece 11 is divided by the processing apparatus 2 or 100, the through-holes 80 (see FIG. 4A) formed in the protective plate 78 may preferably be arranged so that at least one of the through-holes 80 overlaps each device 15 (see FIG. 2). Even after the workpiece 11 is divided into a plurality of device chips, this still enables to suck the individual device chips via the through-holes 80 and to maintain the arrangement of the device chips.

Moreover, the configurations, methods, and the like according to the above-described embodiment can be practiced with changes or modifications as needed to such extent as not departing from the scope of the objects of the present invention.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A chuck table for holding a workpiece under suction, comprising:
a base table having a suction path to be connected to a suction source;
a support member that is mounted on the base table and supports the workpiece; and
a protective plate disposed so as to cover an upper surface of the support member and to protect the support member, wherein
the protective plate has a plurality of through-holes that transmits a suction force from the suction source to the workpiece.

2. The chuck table according to claim 1, wherein the protective plate has a porosity of 5% or higher and 35% or lower.

3. The chuck table according to claim 1, wherein
the base table includes
a support member suction path configured to hold the support member under suction,
a protective plate suction path formed on an outer periphery side of the support member suction path and configured to hold the protective plate at an outer peripheral portion thereof under suction, and
a workpiece suction path configured to hold the workpiece under suction.

4. The chuck table according to claim 1, wherein the protective plate is formed of a transparent body.

5. The chuck table according to claim 1, wherein the support member is formed of a transparent body.

6. The chuck table according to claim 1, wherein the support member is thicker at an outer peripheral portion thereof than at a central portion thereof.

7. The chuck table according to claim 1, wherein the through-holes are formed at a higher density on an outer periphery side than on a center side of the protective plate.

8. A laser processing apparatus comprising:
a chuck table configured to hold a workpiece under suction;
a laser beam application unit configured to apply processing to the workpiece held on the chuck table by irradiating a laser beam to the workpiece; and
a moving unit configured to relatively move the chuck table and the laser beam application unit, wherein
the chuck table includes
a base table having a suction path connected to a suction source,
a support member that is mounted on the base table and supports the workpiece, and
a protective plate disposed so as to cover an upper surface of the support member and to protect the support member,
the protective plate having a plurality of through-holes that transmits a suction force from the suction source to the workpiece.
